(19) United States
(12) Patent Application Publication
(10) Pub. No.: US 2006/0114001 A1
(43) Pub. Date: Jun. 1, 2006

(54) Process and device of high voltage test with detecting function for short/open circuit

(75) Inventors: Yauo-Nan Wang, Taipei CIty (TW); Wen-Chieh Wu, Sanchong City (TW); Szu-Yi Wang, Taipei City (TW)

Correspondence Address: BUCKNAM AND ARCHER, 1077 NORTHERN BOULEVARD, ROSLYN, NY, 11576, US

(73) Assignee: CHROMA ATE INC.

(21) Appl. No.: 11/151,613

(22) Filed: Jun. 13, 2005

(30) Foreign Application Priority Data
Nov. 26, 2004 (TW) 093136412

(51) Int. Cl. G01R 31/08

(52) U.S. Cl. 324/523

(57) ABSTRACT

This invention relates to a process and a device of high voltage test with detecting function for short or open circuits comprises carying out test of short or open circuits with low voltage for an object prior to a high voltage test, checking forrner step properly and then carrying out high voltage test to improve the life time of devices and test points, which also can improve the reliability of test.

### BACKGROUND OF THE INVENTION

Usually, in the quality inspection of electrical products (such as electrical heater, dry-blower, etc) or their parts, it must perform the high voltage test by using high voltage generator, in order to confirm if the test object is or not comply the voltage-withstanding conditions of safety regulations.

During the high voltage test, if the contact condition of testing probe and test object is not good, the arc may occur, and shorten the life time of the contact point if the arc occurs often. Besides, due to the bad contact condition, the high voltage may not exactly transmitted to the test object, and then a deficiency object might be wrong decided as a good object.

To the high voltage generating equipment, the generation of arc may greatly disturb the equipment itself and its accessory testing equipment, and influence the reliability and stability of the equipment, and more over influence the reliability of the testing results.

If the test object presents the short circuit phenomenon and the high voltage is directly added to the test object, it also causes disturbance in some degree to the testing points and testing equipment, and may be the major break down reasons of the equipment.

Most of the high voltage testing equipment today possess the open circuit detecting function. While proceeding the high voltage testing by using direct current source, the instant charging characteristics of the test object is usually checked, because the charging characteristics can be used for judging if the connection of the test object is good or not. But in case of short distance open circuit, the charging may stop after a short time, and the circuit situation may be considered as an open circuit.

While proceeding the high voltage testing by using alternating current source, in case of short distance open circuit, the high voltage may causes the happening of arc, which can reduce the life time of test point and the test equipment.

To increase the stability of output voltage, and to reduce the influence of variation of load to the output voltage, most of the high voltage testing equipment today adopt a constant voltage mode for generating a high voltage test signal. As the short circuit of the test object occurs, although the over current protection is provided and the short circuit is detected, but the test object still impacted by a high energy. And this is also a very bad effect to the test point and test equipment itself.

Issued patent No. 475,992 of Taiwan Patent Office, disclosed a method and equipment for safe high voltage test and FIG. 1 is the circuit block diagram of a high voltage generation apparatus with low output impedance, of the prior art. As shown, this prior art has no mechanism to perform short/open circuit detecting. The method and equipment showed can decide if there is abnormal current occurs, by comparing the high voltage output current and returning current. And if abnormal current is found, the output current might be cut immediately. But this prior art can not detecting short/open circuit of the test object.

### FIELD OF THE INVENTION

This invention relates to a process and a device of high voltage test, more particularly, to a process and a device of high voltage test with detecting function for short or open circuits.

### SUMMARY OF THE INVENTION

To solve the above-mentioned problems, the main purpose of this invention is to provide a process and a device of high voltage test with detecting function for short or open circuits, which comprises carrying out test of short or open circuits with low voltage for an object prior to a high voltage test, this can improve the life time of devices and test points, which also can improve the reliability of test. According to this invention, in order to meet the requirement for different testing phase, it provides a high output impedance voltage source for the short/open circuit testing, and a low voltage variation voltage source for the high voltage testing. With this arrangement, the bad effects due to test object's deficiency and improper connection of the test circuit, can be eliminated.

### BRIEF DESCRIPTION OF THE DRAWINGS

FIG. 1 is the circuit block diagram of a high voltage generation apparatus with low output impedance, of the prior art;

FIG.2 is the circuit block diagram of a high voltage generation apparatus which can select with high or low output impedance, of this invention; and

FIG.3 is the flowchart of the high voltage testing according to the preferred embodiment of this invention.

### DETAILED DESCRIPTION OF THE PREFERRED EMBODIMENT

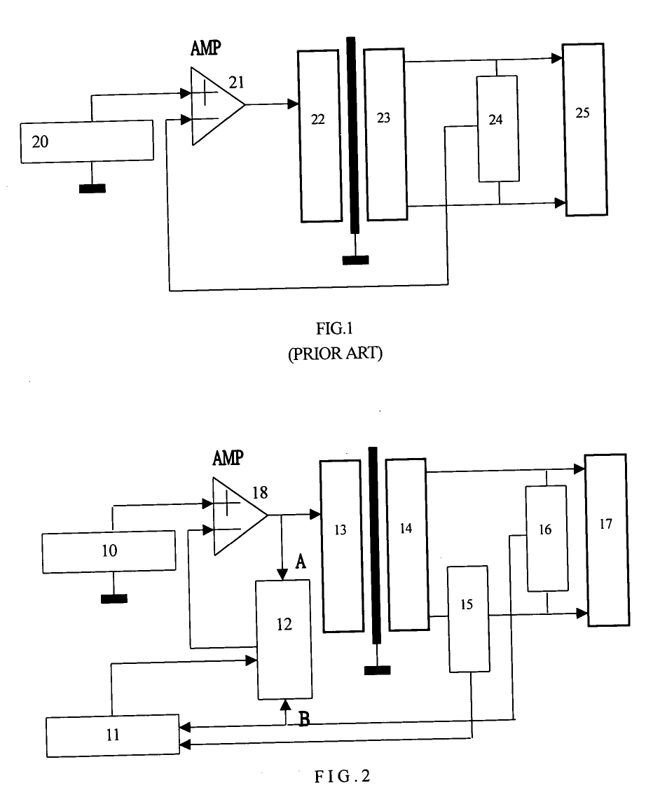

The technical characteristics of this invention could be more obvious while refer to the following descriptions and the related drawings. FIG. 2 is the relating circuit block diagram of the high voltage test device of this invention, the circuit including a alternating current generation apparatus 10, a microprocessor controller 11, a feedback selection 12, a transformer primary 13, a high voltage output 14, a current apparatus 15, a voltage divider 16, a test object 17, and an amplifier 18. The output of the alternating current generation apparatus 10 can be independently controlled either in voltage or frequency. The amplifier 18 is a power amplifier for supplying the required power to the high voltage transformer, in which the primary and secondary of the high voltage transformer is the said transformer primary 13 and said high voltage output 14 respectively. The feedback selection 12 can select the feedback either from the output terminal of the high voltage transformer for operating in constant voltage mode, or the feedback from the output terminal of the amplifier for operating in non-constant voltage mode; feedback point A gets the feedback from the output of the amplifier and feedback point B gets the feedback from the output of the high voltage transformer. The voltage divider 16 is for supplying the tolerance feedback signal. The test object 17 is the object for high voltage test. The current apparatus 15 is for reading and outputting the current value, and the microprocessor controller 11 is for controlling of the feedback selection, and judging if the test object is in short/open circuit or not based on the current value reading.

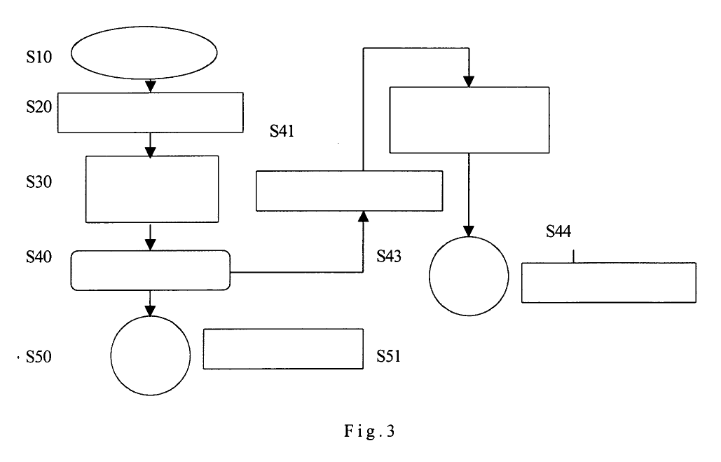

FIG. 3 shows the detail flowchart of the testing procedure of this invention. The testing procedure includes start testing (step S10), select feedback A (step S20), output low voltage and read the current value (step S30), decide if short or open circuit occurs (step S40), select feedback B (step S41), output high voltage and read the current value (step S42), stop testing (step S43), and display the high voltage test results (step S44). In step S40, in case there is short or open circuit of the test object is found, then jump to stop testing (step S50), and display short/open circuit abnormal (step S51).

Refer to FIG. 2 also, as the test object is ready for high voltage test, the testing procedure come to start testing (step S10), then the alternating current generation apparatus 10 output the alternating voltage from 0 to several tens volts or more, supplying the required energy to amplifier 18 for activate the high voltage transformer. At the same tirne, the feedback selection 12 selects feedback A, in which the required control signal for non-constant voltage operation is adopted, then output the low voltage, the current apparatus 15 read the current value (step S30) and then transmit it to microprocessor controller 11, the microprocessor controller 11 compares the received current value with some preset values stored in the microprocessor (these preset values can be changed), if short/open circuit is decided (step S40), stop the testing immediately (step S50) and soon display short/open circuit abnormal (step S51); but if no short/open circuit is decided (step S40), then the feedback selection 12 is switched to B (step S41), and provides the feedback signal passing through the voltage divider 16, this can generate the required control signal for constant voltage operation. The high voltage is outputted from the high voltage transformer, then read the voltage and current values (step S42), stop the testing (step S43) and display the high voltage test results (step S44).

Under the constant voltage operation mode in the above testing procedure, the output voltage can be keep in a certain fixed value. But the actual measured voltage values for vacant load and 30 mA load for the 5 kV rating voltage are as follows:

5 kV vacant load: 4.998 kV

5 kV 30 mA load: 4.993 kV

On the other hand, while the testing is under the non-constant voltage operation mode, undertake the vacant load and 20 kohm load measurement for the 100 Vac rating voltage, we can get the following results:

100V vacant load: 100 V 100 V 20 Kohm load: 50 V

From above results, we can calculate the output impedance of the high voltage transformer is to be 20 Kohm. This can supply the required output impedance for the short/open circuit testing, and can meet the requirement for different testing phase. In other words, it can provide a high output impedance voltage source for the short/open circuit testing, and a low voltage variation voltage source for the high voltage testing. And this can eliminate the bad testing situations, and can avoid the bad effects of the high voltage testing.

Compare to the prior arts, the proposal of this invention have the following merits:

1. Detecting short/open circuit before high voltage testing.

2. Reduce the happening of arc while the high voltage testing, increase the life time of testing contact point.

3. Reduce the happening of arc, increase the reliability of testing equipment itself and other related equipment.

4. Almost no extra material is needed, the said device can perform the high voltage testing.

5. Decrease the probability of miss judgment which can causes the test fails.

6. It can supply the high voltage source with low voltage variation, to meet the requirement of high voltage testing.

Although the invention has been described in connection with a preferred embodiment, but based on the purpose and the field of this invention, it is to be understood that the invention is not to be limited to the disclosed embodiment, but on the contrary, is intended to cover various embodiments and modifications. However, these similar embodiments or modifications shall must included within the spirit and scope of the appended claims.

### List of Referene Numberals

10 AC generation apparatus

11 microprocessor controller

12 feedback selection

13 transformer primary

14 high voltage output

15 current apparatus

16 voltage divider

17 test object

18 amplifier

20 AC generation apparatus

21 amplifier

22 transformer primary

23 high voltage output

24 voltage divider

25 test object

S10 start testing

S20 select feedback A

S30 output low voltage and read the current value

S40 decide if short or open circuit occurs

S41 select feedback B

S42 output high voltage and read the current value

S43 stop testing

S44 display the high voltage test results

S50 stop testing

S5 display short/open circuit abnormal

What is claimed is:

1. A device of high voltage test with detecting function for short/open circuit, comprising:
(a) an alternating current generating apparatus;
(b) a power amplifier, for supplying the required power to the high voltage transformer;
(c) a high voltage transformer;
(d) a feedback selection, to select the feedback either from the output terminal of the high voltage transformer for operating in constant voltage mode, or the feedback from the output terminal of the amplifier for operating in non-constant voltage mode, at which one feedback point get the feedback from the output of the amplifier and another feedback point get the feedback from the output of the high voltage transformer;
(e) a voltage divider, for supplying the tolerance feedback signal; and
(f) a microprocessor controller, for controlling of the feedback selection, and judging if the test object is in short/open circuit or not based on the current value reading;
in which carrying out test of short or open circuits with low voltage for an object prior to a high voltage test, checking former step properly and then carrying out high voltage test to improve the life time of devices and test points, which also can improve the reliability of test.

2. The device of claim 1, wherein the alternating current generating apparatus further comprising an apparatus for controlling the output voltage and frequency.

3. The device of claim 1, wherein the feedback selection is controlled by the microprocessor controller for selecting the deserving feedback points.

4. The device of claim 1, wherein the microprocessor controller can receive the signal from either from voltage divider or current apparatus, digitalize these signal into signal value and compare the signal value with some preset values stored in the microprocessor, and decide if short/open circuit occurs based on the comparison result, the microprocessor controller can also output the test results or values to specific device such as a display.

5. The device of claim 1, wherein the feedback selection is any type of switch and controlled by the said microprocessor controller, for supplying a negative feedback signal to power amplifier and influence the output of the said power amplifier.

6. The device of claim 1, wherein the device further comprises a current apparatus of any type of current measuring equipment which can transmit its measured current value to the said microprocessor controller.

7. A process of high voltage test with detecting ftinction for short/open circuit, comprising the steps of:
feedback selecting, select the feedback signal either from the output terminal of power amplifier or output terminal of high voltage transformer;
carrying out test of short or open circuits with low voltage for an object prior to a high voltage test; and performing the high voltage test after the confirmation of neither short nor open circuit for the object.
